(19) United States
(12) Patent Application Publication
(10) Pub. No.: US 2013/0089982 A1
(43) Pub. Date: Apr. 11, 2013

(54) Method of Fabricating a Substrate Having Conductive Through Holes

(71) Applicants: Shih-Long WEI, Hsinchu County (TW); Shen-Li HSIAO, Hsinchu County (TW); Chien-Hung HO, Hsinchu County (TW)

(72) Inventors: Shih-Long WEI, Hsinchu County (TW); Shen-Li HSIAO, Hsinchu County (TW); Chien-Hung HO, Hsinchu County (TW)

(73) Assignee: Viking Tech Corporation, Hsinchu County (TW)

(21) Appl. No.: 13/410,482

(22) Filed: Mar. 2, 2012

(30) Foreign Application Priority Data
Oct. 11, 2011 (TW) 100136701

(51) Int. Cl. H01L 21/768

(52) U.S. Cl. 438/667; 257/E21.577

(57) ABSTRACT

A method of fabricating a substrate having a plurality of conductive through holes is disclosed. Release films are formed on opposite sides of a substrate, and a plurality of through holes penetrating the release films and the substrate are formed. A first metal layer is formed on the release films and the sidewall of each of the through holes prior to removing the release films and the first metal layer thereon. A second metal layer is formed on the first metal layer on the sidewalls of the through holes by electroless plating. Compared to the prior art, the method is simpler and cheaper to carry out while the conductive through holes and a surface circuit layer thereof are fabricated separately, thereby avoiding disadvantage of forming a circuit layer on the surface of the substrate too thick.

### BACKGROUND OF THE INVENTION

1. Field of the Invention

This invention relates to methods of fabricating a substrate, and, more particularly, to a method of fabricating a substrate having conductive through holes.

2. Description of Related Art

In order to take the full advantage of the substrate area and reduce the transmission route of electronic signals, the substrate has through holes penetrating therethrough and filled with conductive material so as to form conductive through holes for circuits and electronic elements disposed on the substrate to be electrically connected thereto.

Referring to FIG. 1, a cross-sectional diagram of a substrate having conductive through holes in accordance with the prior art is provided. A plurality of through holes 100 are formed to penetrate a substrate 10, and metal masks 11 are disposed on both surfaces of the substrate 10. Each of the metal masks 11 has a plurality of openings 110 corresponding in position to the through holes 100. The through holes 100 are filled with a conductive paste 12 by extrusion or vacuum suction.

However, the metal masks 11 are subject to a misalignment problem, especially at the edges of the substrate 10, where misalignment accumulates. As a result, the conductive paste 12 cannot be filled well in the through holes 100.

Another method of fabricating conductive through holes in a substrate is disclosed by TW Patent, No. 540279. A substrate is drilled to form through holes. A seed layer is then formed on the substrate and the sidewalls of the through holes via a sputtering process. An electroless copper plating process is then performed to the through holes and the substrate. A dry film is then laminated on the substrate and a lithography process is performed so as to form a plurality of openings in the dry film. An electroplating copper plating process is performed to fill up the through holes and form circuits on the substrate. The dry film and the seed layer covered by the dry film are removed, and nickel and gold plating layer is formed on the copper layer so as to form the conductive through holes and surface circuits simultaneously.

However, the aforementioned plating of the through holes is performed from the sidewall to the center of the substrate by copper plating process. The overall process is complicated and it is not easy to completely fill up the through holes. Furthermore, during performing copper plating process, the copper layer is deposited in the through holes and on the substrate simultaneously. In order to fully fill the through holes with copper metal, time for copper plating process has to be increased. At the same time, the thickness of the copper layer on the surface of the substrate are increased due to such a long time process. And it leads to the copper layer formed on the surface of the substrate becoming too thick such that the overall thickness of the substrate exceeds the required specification of clients. Moreover, dimples are readily formed on the surface of the substrate at the through holes due to the inherent problem of electroplating filling. Besides, the longer time of overall process also affects the yield and cost of substrates.

Therefore, how to overcome the abovementioned problems of complicated and time consuming formation of conductive through hole process, poor quality of the conductive through hole, too thick copper layer on the surface of the substrate, and the like of the prior art and further to increase the yield and decrease cost of substrates is becoming critical to be solved.

### SUMMARY OF THE INVENTION

In view of above-mentioned problems of the prior art, this invention provides a method of fabricating a substrate having conductive through holes, comprising: forming release films on opposite sides of a substrate; forming a plurality of through holes penetrating the release films and the substrate; forming a first metal layer on the release films and the sidewall of each of the through holes; removing the release films and the first metal layer thereon; and forming a second metal layer on the first metal layer and on the sidewalls of the through holes by electroless plating.

In an embodiment, the method further comprises forming a patterned metal layer electrically connected to the second metal layer on the substrate body, and the through holes are completely or incompletely filled up with the second metal layer.

According to the abovementioned method, if the through holes are incompletely filled up with the second metal layer, the method further comprises forming a patterned metal layer which is electrically connected to the second metal layer on the substrate body and fills up the through holes at the same time.

In an embodiment, the release films are formed by lamination, coating, or spray, and the through holes are formed by laser drilling or etching.

In another embodiment, the first metal layer is formed by sputtering, evaporation, electroless plating, or chemical vapor deposition, and the first metal layer is made of a material of activated palladium, sputtered nickel, or copper, or the like.

In the method of fabricating the substrate having the conductive through holes, the release films are removed by peeling off, burning out, or chemical liquid dissolving, and the second metal layer is made of a material of nickel.

In conclusion, the method of fabricating the substrate having the conductive through holes of this invention is free from the misalignment problem of the prior art by self-deposition of metal in the through holes. In addition, the conductive through holes and a surface circuit layer of this invention are fabricated separately such that the thickness of the circuit layer can be fabricated according to requirements of clients without being limited by the fabricating process of the conductive through holes.

### BRIEF DESCRIPTION OF DRAWINGS

FIG. 1 is a cross-sectional diagram of a substrate having a plurality of conductive through holes in accordance with the prior art; and

FIGS. 2A-2F are cross-sectional diagrams illustrating a method of fabricating a substrate having a plurality of conductive through holes in accordance with the present invention, wherein FIGS. 2E′ and 2F′ are other embodiments of FIGS. 2E and 2F, respectively.

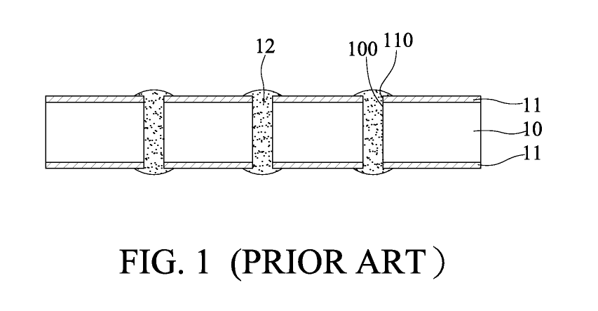

### DETAILED DESCRIPTION OF PREFERRED EMBODIMENTS

The following illustrative embodiments are provided to illustrate the disclosures of this invention, these and other advantages and effects can be apparently understood by those in the art after reading the disclosures of this specification.

Note that the structures, proportions, sizes depicted in the accompanying figures merely illustrate the disclosures of the specification to allow for comprehensive reading without a limitation to the implementation or applications of this invention, and does not constitute any substantial technical meaning. Any variations or alterations to the structures, proportional relations or sizes should be encompassed within the scope of the disclosures without affecting effects generated by and objectives achieved by this invention. Meanwhile, the terms that are quoted in the explanation like “upper,” “side,” “a” and so on only intent for convenience of description rather than limiting feasible scope of the disclosed embodiments. Change or adjustment of relative relationship under no actual alteration of content of technique should be seen as feasible scope of the disclosed embodiments.

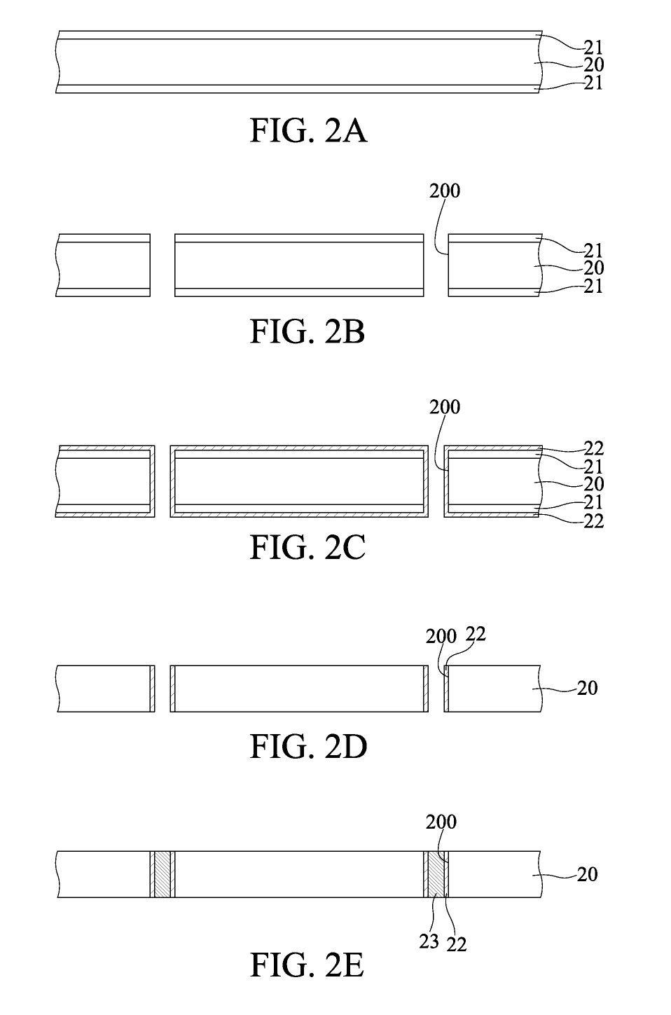

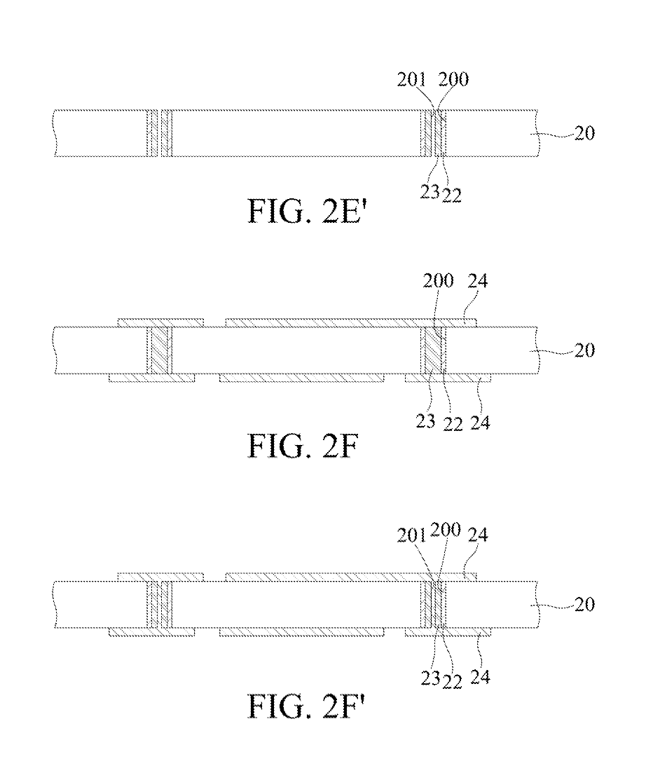

Referring to FIGS. 2A-2F, cross-sectional diagrams illustrating a method of fabricating a substrate having a plurality of conductive through holes according to the present invention are provided, wherein FIGS. 2E′ and 2F′ are other embodiments of FIGS. 2E and 2F, respectively.

As illustrated in FIG. 2A, release films 21 are formed on opposite sides of a substrate body 20. The release films 21 can be formed by, but not limit to, lamination, coating, or spray, and the substrate 20 can be, but not limit to, a ceramic substrate.

As illustrated in FIG. 2B, a plurality of through holes 200 penetrating the release films 21 and the substrate body 20 are formed. The through holes 200 can be formed by, but not limit to, laser drilling or etching.

As illustrated in FIG. 2C, a first metal layer 22 is formed on the release films 21 and the sidewall of each of the through holes 200. The first metal layer 22 can be formed by, but limit to, sputtering, evaporation, or chemical vapor deposition. Alternatively, the first metal layer 22 can be formed by activating process of electroless plating. In addition, the first metal layer 22 can be made of, but not limit to, activated palladium, sputtered nickel or copper, or the like.

As illustrated in FIG. 2D, the release films 21 and the first metal layer 22 thereon are removed. The release films 21 can be removed by, but not limit to, peeling off, burning out or chemical liquid dissolving.

As illustrated in FIGS. 2E and 2E′, a second metal layer 23 is formed on the first metal layer 22 on the sidewalls of the through holes 200 by electroless plating and the second metal layer 23 can be made of a material of nickel. As illustrated in FIG. 2E, the through holes 200 can be filled up with the second metal layer 23. Alternatively, as illustrated in FIG. 2E′, the through holes 200 can be incompletely filled with the second metal layer 23 such that a gap 201 can be formed in the through holes 200.

As illustrated in FIGS. 2F and 2F′, a patterned metal layer 24 electrically connected to the second metal layer 23 can be formed on the substrate 20 by thin-film process, such as sputtering, lithography, electroplating, etching, or electroless plating process so as to be used as a circuit layer. FIGS. 2F and 2F′ continue with FIGS. 2E and 2E′, respectively. Specifically, as illustrated in FIG. 2F′, the patterned metal layer 24 can further fill up the through holes 200. In other words, the patterned metal layer 24 is filled in the gap 201.

In conclusion, compared with the prior art, the method of fabricating the substrate having the conductive through holes is free from the misalignment problem and the surface thereof is much flatter by self-deposition of metal in the through holes. In addition, the conductive through holes and a surface circuit layer of this invention are fabricated separately such that the thickness of the circuit layer can be fabricated according to requirements without being affected by the fabricating process of the conductive through holes.

The foregoing embodiments are exemplarily illustrated to disclose the principles and effects of this invention and not restrictive of the scope of this invention. One skilled in the art could modify the previous embodiments without violating the spirit and scope of this invention. Hence, it should be understood to those in the art that the disclosures of this invention should fall within the scope of the appended claims.

What is claimed is:

1. A method of fabricating a substrate having a plurality of conductive through holes, comprising:
forming release films on opposite sides of a substrate;
forming a plurality of through holes penetrating the release films and the substrate;
forming a first metal layer on the release films and a sidewall of each of the through holes;
removing the release films and the first metal layer thereon; and
forming a second metal layer on the first metal layer on the sidewalls of the through holes by electroless plating.

2. The method of claim 1, further comprising forming on the substrate a patterned metal layer electrically connected to the second metal layer.

3. The method of claim 1, wherein the through holes are completely or incompletely filled with the second metal layer.

4. The method of claim 3, wherein when the through holes are incompletely filled with the second metal layer, they are further filled with a patterned metal layer electrically connected to the second metal layer on the substrate.

5. The method of claim 1, wherein the release films are formed by lamination, coating, or spray.

6. The method of claim 1, wherein the through holes are formed by laser drilling or etching.

7. The method of claim 1, wherein the first metal layer is formed by sputtering, evaporation, electroless plating, or chemical vapor deposition.

8. The method of claim 1, wherein the first metal layer is made of activated palladium, or sputtered nickel, or copper.

9. The method of claim 1, wherein the release films are removed by peeling off, burning out, or chemical liquid dissolving.

10. The method of claim 1, wherein the second metal layer is made of nickel.
